(19) United States
(12) Patent Application Publication
(10) Pub. No.: US 2009/0032297 A1
(43) Pub. Date: Feb. 5, 2009

(54) COMPONENT CASING COMPRISING A MICRO CIRCUIT

(76) Inventors: Sampo Aallos, Tampere (FI); Klaus Turhanen, Muijala (FI)

Correspondence Address: STITES & HARBISON PLLC, 1199 NORTH FAIRFAX STREET, SUITE 900, ALEXANDRIA, VA, 22314, US

(21) Appl. No.: 12/095,846

(22) PCT Filed: Dec. 1, 2006
(86) PCT No.: PCT/FI2006/000398

§ 371 Date: Aug. 7, 2008

(30) Foreign Application Priority Data
Dec. 1, 2005 (FI) 20051228

(51) Int. Cl. H05K 1/16

(52) U.S. Cl. 174/260

(57) ABSTRACT

A component case comprising one or more micro circuits (6), where the micro circuit component is placed on a base, most suitably on a printed circuit board and said component is joined to the base with a known reversing circuit or thread bonding techniques and the base has elevations (5) placed around said component. The base is flexible and in order to stiffen the structure a stiff structure is placed on it, as a sheet metal (10), a component or another similar structure of layers and the inside centre space of the case is filled with glue or plastic.

The invention relates to a component casing comprising one or more micro circuits, where the micro circuit component is placed on a base, most suitably on a printed circuit board and said component is joined to the base with known reversing circuit or thread bonding techniques and the base has elevations placed around the component, and on top of them a cover is placed that closes the case.

Previously are known circuit case structures meant for surface joint, as IC circuit cases, in which there is

### 1.1 Metal Frame and Plastic Case

The circuit is installed in the middle of the metal frame an thread bonded in the frame strips. The metal case is moulded in the plastic case and the metal edge is cut off.

### 1.2 Stiff Laminate Base

A stiff laminate base is used, usually of printed circuit board material: The laminate has many conductive layers. The micro circuit is installed on them by means of reversing circuit or thread bonding techniques. On the circuit a plastic cover is moulded. On the under side there are joint contacts for joining the component by moulding to the final product.

In the disclosed invention a notable improvement in the prevailing prior art is presented, and characteristic of the first embodiment of the component case according to this invention is that the base is flexible and in order to stiffen the structure, on top of it a stiff structure is placed, as a sheet metal, a component or an other similar structure of layers and the centre space of the case is filled with glue or plastic.

Characteristic of the second embodiment according to the invention is that the base is flexible and in order to stiffen the structure, on top of it another flexible substructure is placed, as an other printed circuit board and the centre space of the case is filled with glue or plastic material.

The advantages of the component case according to the invention is that components can be placed extremely tight in many layers, whereby the tightness of packing grows. The joints between the layers can be made, for instance, by soldering. However, the component structure can be better tested than the present alternatives. The flexible base makes also possible the turning of the case to an angle of 90 degrees to the sides of the case or otherwise into another almost free form.

In the following the invention is disclosed with reference to the enclosed drawing, where

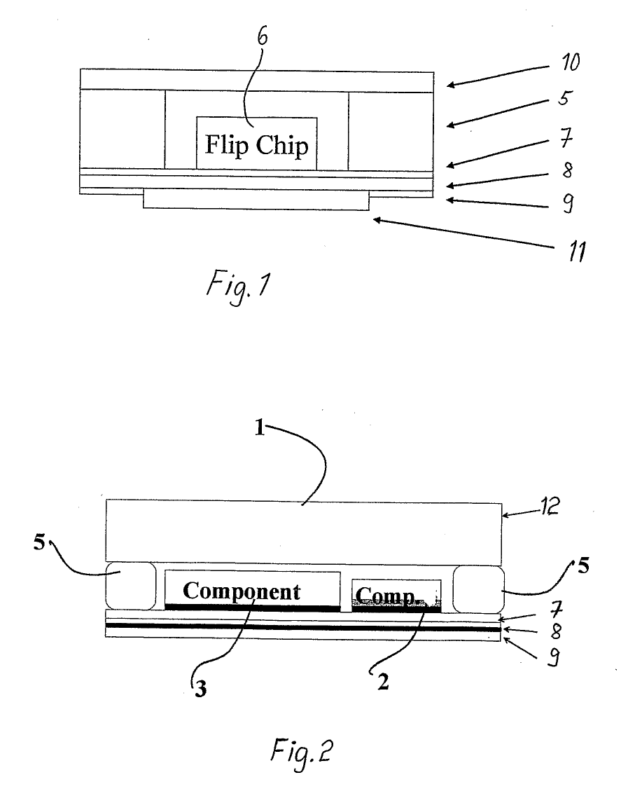

FIG. 1 shows a layer structure of the component case stiffened with a sheet,

FIG. 2 shows the structure of the component case stiffened with a component.

FIG. 1 shows an IC circuit case, where a circuit 6 is placed on top of a thin flexible base of 100 μm or under 100 μm. The base is flexible at least in one direction. The base is formed of the surface protecting film 7, conductive frame 8, including a copper part, and of protecting film 9, under it. IC circuit 6 is protected by edge part 5 winding around it, the height of which is 125 μm. The elevations of the edge part are fixed to the base by gluing and edge parts 5 are moulded on the base. On the edge part a sheet 10 is fixed, which stiffens the structure. The elevations do not form any electric connection from the base to the uppermost sheet 10. The uppermost sheet is only a protective stiffening sheet. On the case under side there is yet a protection for the soldering, for instance of a thickness of 25 μm.

FIG. 2 shows another implementation of the first embodiment, where the components 3 and 2 of the IC circuit are by means of elevations 5 in a cavity on the base, while the base is as shown in FIG. 1. The stiffness of structure is made in fixing component 1 on elevations 5. In connection with component 1 there can also be some sheet structure 12 included. Necessary electric connection from the base to the component on the upper side is arranged through elevations 5. In this case the case is stiffened by means of component 1 placed on elevations 5.

In the second embodiment of the invention the cover of the case is also a flexible film, a printed circuit boar or similar, and stiffness of the case is achieved by filling the case with glue or another known filling.

Furthermore, the stiffness of case can be made, for instance fixing another case by gluing on elevations 5 of the former case. In any case, the cavity remaining between elevations 5 can, if wanted, be filled with glue or plastic or some other known filling, when components 2, 3, 6 have been placed.

1. A component case comprising one or more micro circuits, where the micro circuit component is placed on a base, most suitably on a printed circuit board and said component is joined to the base by means of known reversing circuit or thread bonding techniques and the base has elevations placed around said component, and on top of them a cover is placed, that closes the case, characterized in that the base is flexible and in order to stiffen the structure a stiff structure is placed on it, as a sheet metal, component or another similar structure of layers and the inside centre space of the case is filled with glue or plastic.

2. A component case comprising one or more micro circuits, where the micro circuit component is placed on a base, most suitably on a printed circuit board and the said component is joined to the base by means of known reversing circuit or thread bonding techniques and the base has elevations placed around said component, and on top of them a cover is placed, that closes the case, characterized in that the base is flexible and in order to stiffen the structure another flexible structure, as a second printed circuit board is placed on it and the inside centre space of the case is filled with glue or plastic.

3. A component case according to claim 1, characterized in that the elevations are made by moulding them of composition metal or they are glued elevation parts.

4. A component case according to claim 1, characterized in that elevations form an electric contact to a component or to an other flexible base working as stiffener on the case.

5. A component case according to claim 1, characterized in that there are elevations at least on two sides of the component.

6. A component case according to claim 1, characterized in that the base is a film being flexible in two directions.

7. A component case according to claim 1, characterized in that that the component case is formed of several case layers.

8. A component case according to claim 2, characterized in that the elevations are made by moulding them of composition metal or they are glued elevation parts.

9. A component case according to claim 2, characterized in that elevations form an electric contact to a component or to an other flexible base working as stiffener on the case.

10. A component case according to claim 2, characterized in that there are elevations at least on two sides of the component.

11. A component case according to claim 2, characterized in that the base is a film being flexible in two directions.
